(19) United States
(12) Patent Application Publication
(10) Pub. No.: US 2018/0019510 A1
(43) Pub. Date: Jan. 18, 2018

(54) TERMINATION CIRCUIT, WIRELESS COMMUNICATION DEVICE AND TERMINATION METHOD

(71) Applicant: NEC Corporation, Tokyo (JP)

(72) Inventor: Shiro HIROSAKA, Tokyo (JP)

(73) Assignee: NEC Corporation, Tokyo (JP)

(21) Appl. No.: 15/549,863

(22) PCT Filed: Feb. 1, 2016
(86) PCT No.: PCT/JP2016/000491

§ 371 Date: Aug. 9, 2017

(30) Foreign Application Priority Data
Feb. 27, 2015 (JP) 2015-038200

(51) Int. Cl. H01P 1/26; H01P 3/08; H05K 1/02; H05K 1/18

(52) U.S. Cl. CPC H01P 1/268; H05K 1/181; H01P 3/08; H05K 1/0246; H05K 2201/10015

(57) ABSTRACT

A termination circuit terminates a transmission line through which a signal in a high frequency range propagates with excellent termination characteristics. The termination circuit includes a transmission line through which a high frequency signal propagates and capacitive elements terminating the high frequency signal from the transmission line. The transmission line is configured as a transmission line through which the high frequency signal propagates. The capacitive elements are configured as a capacitive element array in which those are connected in cascade, and configured to be connected to an end of the transmission line.

### TECHNICAL FIELD

The present invention relates to a termination circuit, a wireless communication device and a termination method.

### BACKGROUND ART

In a wireless transmitting/receiving device, a circuit terminating an end of a line is disposed. For example, a strip line termination circuit terminating a strip line using an open stub (Patent Literature 1), a termination circuit decreasing an inductance component at an end of a line by connecting a plurality of resistors in parallel between the end of the line and the ground (Patent Literature 2), and a termination circuit of micro strip using an impedance conversion unit and a capacitive stub in combination (Patent Literature 3).

Further, in recent years, as a price of a microwave transmitting/receiving device has been reduced, components heretofore integrated in a package have been surface-mounted on a printed circuit board.

When the above technique is applied to a high frequency range, the following problems may occur. In the strip line termination circuit described in Patent Literature 1, a contribution of the inductance component in the high frequency range (e.g. equal to or more than 20 GHz) increases, and sufficient termination characteristics cannot be obtained. According to a configuration described in Patent Literature 1, in the high frequency range of equal to or more than 20 GHz, the reflection coefficient (return loss) of the strip line termination circuit may be only about −6 dB and it is not sufficient as the termination characteristic. In the termination circuit described in Patent Literature 2, in the high frequency range, the termination characteristics deteriorate depending on distances of resistors connected in parallel. Further, in the termination circuit of micro strip described in Patent Literature 3, in the high frequency range, the impedance conversion unit needs to convert to higher impedance as a frequency becomes higher. Therefore, when a line width enabling the high impedance cannot be achieved due to restrictions such as processing precision, it is impossible to form the impedance conversion unit in the first place.

### CITATION LIST

### Patent Literature

[Patent Literature 1] Japanese Unexamined Patent Application Publication No. 1-190003

[Patent Literature 2] Japanese Unexamined Patent Application Publication No. 64-23628

[Patent Literature 3] Japanese Unexamined Patent Application Publication No. 5-75311

### SUMMARY OF INVENTION

### Technical Problem

However, the inventor has found out problems described below in the above-mentioned technologies. In the case where the transmission line is surface-mounted on the printed circuit board, for example, when attempting to achieve the configuration described in Patent Literature 2, a chip resistor is used as the resistor. In this case, the chip resistor is larger in size than an alumina resistor, etc. used in the package, and the inductance component becomes larger. As a result, in the high frequency range, the reflection characteristics at a terminal end deteriorate. Therefore, in high frequency circuits, it is required that a termination method independent of resistive elements is established.

The present invention has been made in view of the aforementioned circumstances and aims to terminate a transmission line with excellent termination characteristics in a high frequency range.

### Solution to Problem

An aspect of the present invention is a termination circuit including: a transmission line through which a high frequency signal propagates; and one or a plurality of capacitive elements connected in cascade connected to an end of the transmission line.

An aspect of the present invention is a termination method including connecting one or a plurality of capacitive elements connected in cascade to an end of a transmission line through which a high frequency signal propagates to terminate the transmission line.

### Advantageous Effects of Invention

According to the present invention, it is possible to terminate a transmission line with excellent termination characteristics in a high frequency range.

### BRIEF DESCRIPTION OF DRAWINGS

FIG. 1 is a diagram schematically illustrating a configuration of a termination circuit according to a first exemplary embodiment;

FIG. 2 is a graph illustrating reflection characteristics of an example of a chip multilayer ceramic capacitor;

FIG. 3 is a graph illustrating insertion loss of the example of the chip multilayer ceramic capacitor;

FIG. 4 is a diagram illustrating a reflection coefficient and the insertion loss of each of capacitive elements of the termination circuit according to the first exemplary embodiment;

FIG. 5 is a graph illustrating a relation between number of the capacitive elements and the reflection coefficient Γ(ALL) of the entire termination circuit when total reflection is achieved at the end of the termination circuit under a calculation condition of the first exemplary embodiment;

FIG. 6 is a graph illustrating frequency dependence of the reflection coefficient Γ(ALL) of the entire termination circuit 100 when the number of the capacitive elements is nine under the calculation condition of the first exemplary embodiment;

FIG. 7 is a diagram schematically illustrating a configuration of a termination circuit according to a second exemplary embodiment; and

FIG. 8 is a graph illustrating frequency dependence of a reflection coefficient Γ(ALL) of the entire termination circuit when number of the capacitive elements is nine in the second exemplary embodiment.

### DESCRIPTION OF EMBODIMENTS

Exemplary embodiments of the present invention will be described below with reference to the drawings. The same components are denoted by the same reference numerals throughout the drawings, and a repeated explanation is omitted as needed.

### First Exemplary Embodiment

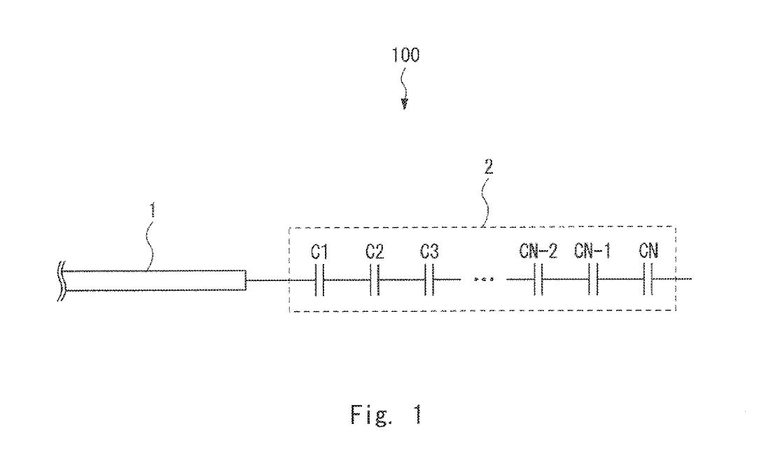

A termination circuit according to a first exemplary embodiment will be described. FIG. 1 is a diagram schematically illustrating a configuration of a termination circuit 100 according to a first exemplary embodiment. The termination circuit 100 includes a transmission line 1 and a capacitive element array 2. The transmission line 1 and the capacitive element array 2 are surface-mounted on a printed circuit board, for example.

The transmission line 1 is a transmission line through which a high frequency signal propagates. In FIG. 1, the high frequency signal propagates from left to right on the paper.

The capacitive element array 2 has a configuration in which one or more capacitive elements are connected in cascade. Here, the capacitive element array 2 has a configuration in which N (N is an integer greater than or equal to one) capacitive elements C1 to CN are connected in cascade. One end of the capacitive element C1 at an end of the capacitive element array 2 is connected to an end of the transmission line 1. In this example, an end of the capacitive element CN opposite to the capacitive element CN-1 is open. Note that the end of the capacitive element CN opposite to the capacitive element CN-1 may be grounded. The capacitive elements C1 to CN are, for example, chip capacitors including chip multilayer ceramic capacitors surface-mounted on the printed circuit board on which the transmission line 1 and the capacitive element array are mounted.

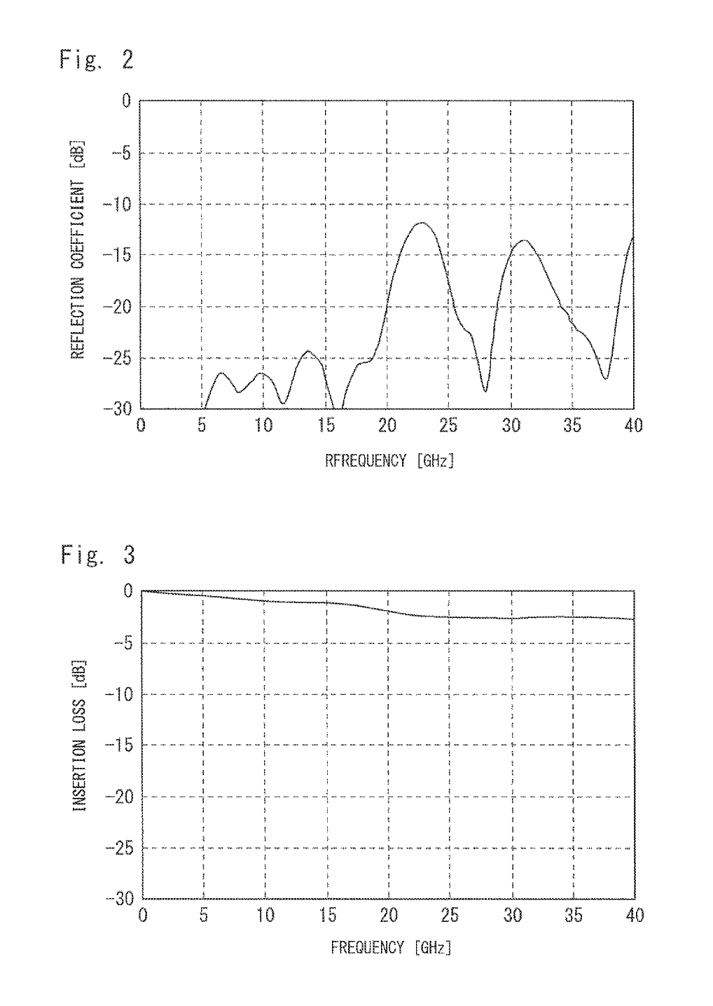

Hera, an example of the chip multilayer ceramic capacitor will be described. FIG. 2 is a graph illustrating reflection characteristics of the example of the chip multilayer ceramic capacitor. FIG. 3 is a graph illustrating insertion loss of the example of the chip multilayer ceramic capacitor. In FIGS. 2 and 3, the horizontal axis represents a frequency of the signal. In FIGS. 2 and 3, the characteristics of the chip multilayer ceramic capacitor of 1005 size, 100000[pF] capacity, and X7R thermal characteristics are illustrated as an example. Note that the characteristics illustrated here is in a case where the chip multilayer ceramic capacitor is inserted in a normal transmission line, not in a case where it is used as a termination circuit. As illustrated in FIG. 2, the chip multilayer ceramic capacitor has a reflection coefficient of about −12 dB or less at a frequency of 20 GHz or higher. As illustrated in FIG. 3, the insertion loss increases as the frequency increases in the chip multilayer ceramic capacitor.

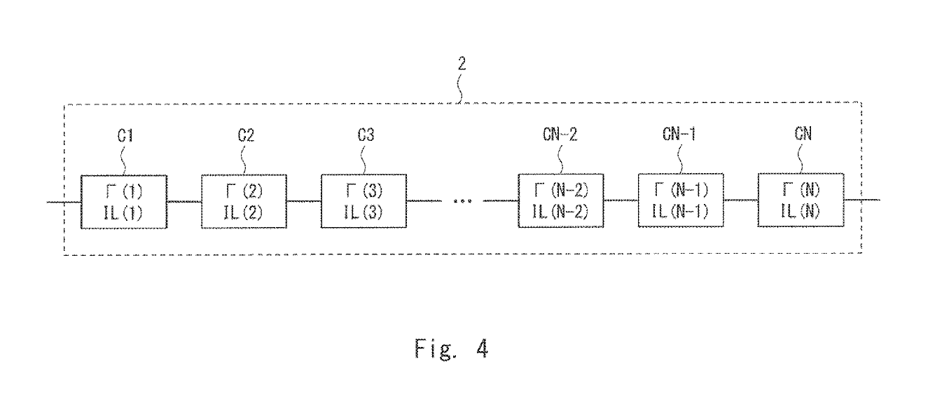

Subsequently, termination performance of the termination circuit 100 will be discussed. FIG. 4 is a diagram illustrating the reflection coefficient and the insertion loss of each of the capacitive elements C1 to CN of the termination circuit 100 according to the first exemplary embodiment. As illustrated in FIG. 4, the reflection coefficients of the capacitive elements C1 to CN are denoted by Γ(1) to Γ(N), respectively. The insertion losses of the capacitive elements C1 to CN are denoted by IL(1) to IL(N), respectively.

In this case, the reflection coefficient Γ(ALL) of the entire termination circuit 100 is expressed by the following expression (1) or (2). Note that, in the expressions (1) and (2), multiple reflections are ignored in the termination circuit 100. Further, in the expression (1), the reflection coefficient Γ(ALL) for characteristic impedance of the transmission line 1 is approximately obtained.

$$\begin{matrix}[ Expression 1 ] & \\ Γ ( ALL ) = Γ ( 1 ) ( N = 1 ) & ( 1 ) \\ [ Expression 2 ] & \\ Γ ( ALL ) = Γ ( 1 ) + {\sum }_{k = 2}^{N} \{ {\{ {\prod }_{j = 2}^{k} IL ( j - 1 ) \}}^{2} \cdot Γ ( j ) ] & ( 2 )\end{matrix}$$

For example, in the expression (2), it is assumed that number of the capacitive elements is nine and total reflection is achieved at the end of the termination circuit 100. In this case, it can be regarded that nine capacitive elements and one totally reflective element are connected in cascade. Thus, N=10 is established here. In this state, the reflection coefficient of each capacitive element is 15 dB (0.0316), the reflection coefficient Γ(10) of the total reflective element is 1, and the insertion loss of each capacitive element is 2 dB (0.631). Note that, here, the conditions of the reflection coefficient and the insertion loss are referred to as a calculation condition in the present exemplary embodiment. Under this condition, the reflection coefficient Γ(ALL) of the entire termination circuit 100 is −12.7 dB (0.5227). The chip capacitor including the chip multilayer ceramic capacitor described above can function as a loss circuit satisfying the calculation condition of the present exemplary embodiment.

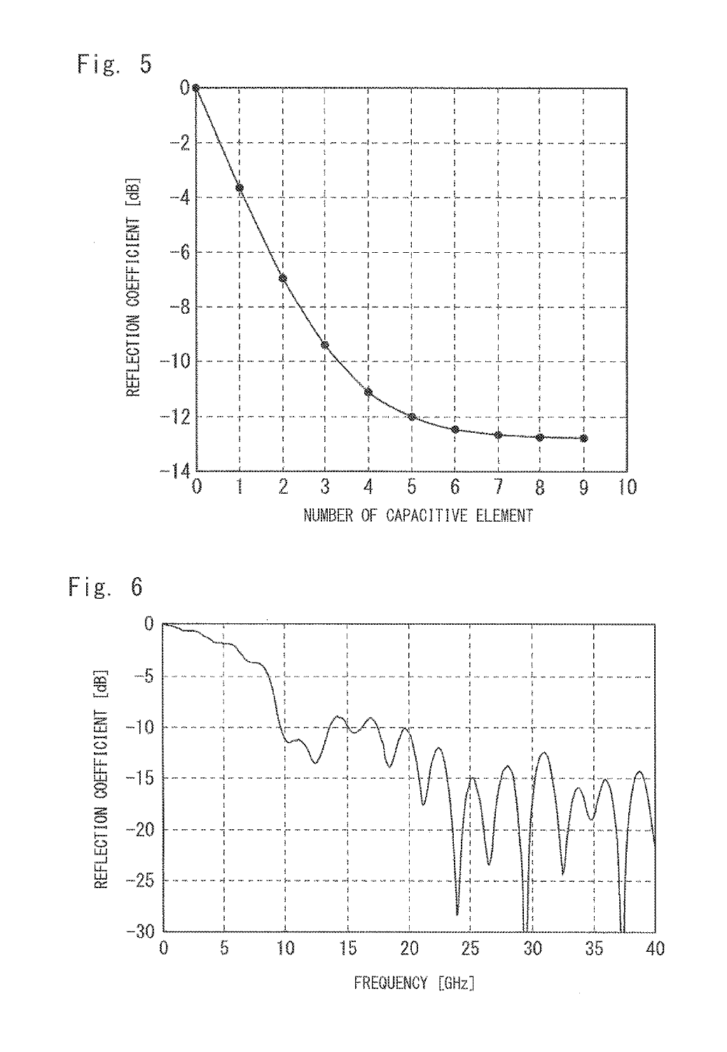

FIG. 5 is a graph illustrating a relation between the number of the capacitive elements and the reflection coefficient Γ(ALL) of the entire termination circuit 100 when total reflection is achieved at the end of the termination circuit 100 under a calculation condition of the first exemplary embodiment. As illustrated in FIG. 5, the reflection coefficient Γ(ALL) of the entire termination circuit 100 decreases as the number of the capacitive elements increases. In this example, the reflection coefficient Γ(ALL) of the entire termination circuit 100 sharply decreases as a whole in a range where the number of the capacitive elements is zero to five (0≦N≦1), and the reflection coefficient Γ(ALL) of the entire termination circuit 100 gradually decreases as a whole in a range where the number of the capacitive elements is six or more (N≧6).

FIG. 6 is a graph illustrating frequency dependence of the reflection coefficient Γ(ALL) of the entire termination circuit 100 when the number of the capacitive elements is nine under the calculation condition of the first exemplary embodiment. As illustrated in FIG. 6, it can be understood that in a high frequency range of 25 to 40 GHz, the reflection coefficient Γ(ALL) of the entire termination circuit 100 can be suppressed to less than −12 dB.

As described above, according to the present configuration, it is possible to provide a termination circuit that achieves advantageous termination characteristics in a high frequency range of equal to or more than 20 GHz, preferably in a high frequency range of equal to or more than 25 GHz by connecting one or a plurality of the capacitive elements connected in cascade to the end of the transmission line. In other words, it is possible to provide a termination circuit having the excellent termination characteristics and configured by using the capacitive element instead of a resistive element in the high frequency range.

Further, when the chip capacitor is used as the capacitive element, a termination circuit having the excellent termination characteristics can be achieved even when the transmission line is mounted on the printed circuit board.

### Second Exemplary Embodiment

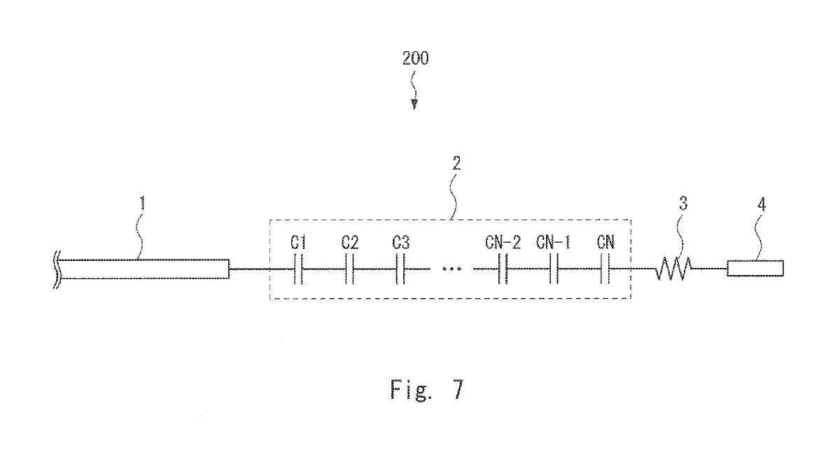

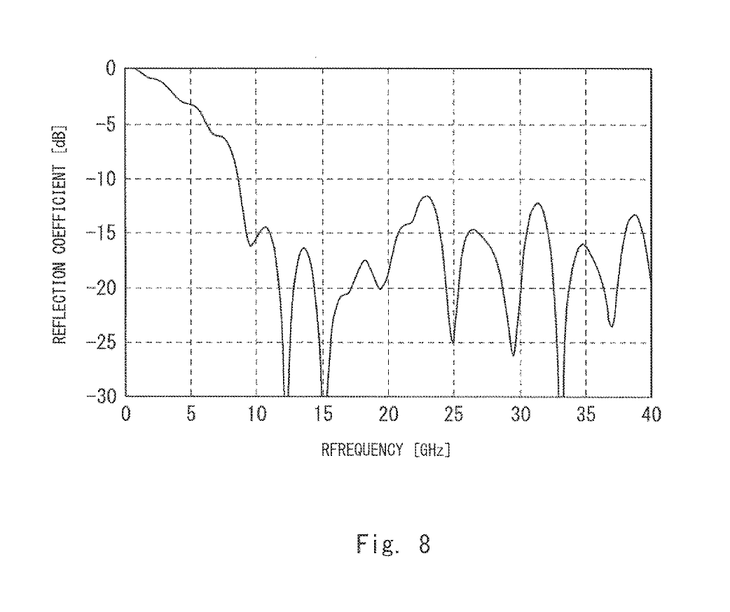

A termination circuit according to a second exemplary embodiment will be described. FIG. 7 is a diagram schematically illustrating a configuration of a termination circuit 200 according to the second exemplary embodiment. The termination circuit 200 has a configuration in which a resistive element 3 and a stub 4 are added to the termination circuit 100 according to the first exemplary embodiment.

The resistive element 3 is inserted between an end of the capacitive element CN opposite to the capacitive element CN-1 and one end of the stub 4. The end of the stub 4 opposite to the resistive element 3 is open. Note that the resistive element 3 may be grounded.

Next, termination performance of the termination circuit 200 will be discussed. Here, the same calculation condition as in the first exemplary embodiment is used as an experimental condition, the termination characteristics are measured with N=10. FIG. 8 is a graph illustrating frequency dependence of the reflection coefficient Γ(ALL) of the entire termination circuit 200 when the number of the capacitive elements is nine. As illustrated in FIG. 8, it can be understood that in a high frequency range of 10 to 40 GHz, the reflection coefficient Γ (ALL) of the entire termination circuit 200 can be suppressed to less than −12 dB.

As described above, according to the present configuration, it is possible to provide a termination circuit that achieves excellent termination characteristics in a high frequency range of equal to or more than 10 GHz by connecting one or a plurality of the capacitive elements connected in cascade and further connecting the resistive element and the stub to the end of the transmission line. Therefore, according to the present configuration, it is possible to provide a termination circuit that achieves more advantageous termination characteristics as compared with the termination circuit 100 according to the first exemplary embodiment.

Further, when the chip capacitor is used as the capacitive element, a termination circuit having the excellent termination characteristics can be achieved even when the transmission line, the resistive element and the stub are mounted on the printed circuit board.

### Other Exemplary Embodiments

The present invention is not limited to the above-described exemplary embodiments, and can be modified as appropriate without departing from the scope of the invention. For example, although the above-described capacitive element is described as the chip capacitor by way of example, this is merely an example. It goes without saying that other capacitors can be used.

In the high frequency range of equal to or more than 20 GHz, if it is possible to achieve the reflection coefficient of 15 dB and the insertion loss of 2 dB per element, not only the capacitive element (capacitor) but also other types of elements can be used.

The termination circuit described in the above exemplary embodiments can be mounted on various communication devices that achieve high frequency communication such as a wireless communication device.

The present invention has been described above with reference to the exemplary embodiments, but the present invention is not limited to the above exemplary embodiments. The configuration and details of the present invention can be modified in various ways which can be understood by those skilled in the art within the scope of the invention.

This application is based upon and claims the benefit of priority from Japanese patent application No. 2015-38200, filed on Feb. 27, 2015, the disclosure of which is incorporated herein in its entirety by reference.

### REFERENCE SIGNS LIST

1 TRANSMISSION LINE
2 CAPACITIVE ELEMENT ARRAY
3 RESISTIVE ELEMENT
4 STUB
100, 200 TERMINATION CIRCUITS
C1 TO CN CAPACITIVE ELEMENTS

1. A termination circuit comprising:
a transmission line through which a high frequency signal propagates; and
one or a plurality of capacitive elements connected in cascade connected to an end of the transmission line.

2. The termination circuit according to claim 1, wherein the end of the one or the plurality of capacitive elements connected in cascade opposite to the transmission line is open or grounded.

3. The termination circuit according to claim 1, wherein
the transmission line is mounted on a printed circuit board, and
the one or the plurality of capacitive elements connected in cascade are chip capacitors surface-mounted on the printed circuit board.

4. The termination circuit according to claim 1, further comprising:
a stub connected to the end of the one or the plurality of capacitive elements connected in cascade opposite to the transmission line, and
a resistive element inserted between the one or the plurality of capacitive elements connected in cascade and the stub.

5. The termination circuit according to claim 4, wherein the end of the stub opposite to the transmission line is open or grounded.

6. The termination circuit according to claim 4, wherein
the transmission line, the resistive element and the stub are surface-mounted on a printed circuit board, and
the one or the plurality of capacitive elements connected in cascade are chip capacitors surface-mounted on the printed circuit board.

7. The termination circuit according to claim 1, wherein the one or the plurality of capacitive elements connected in cascade have a reflection coefficient of 15 dB and an insertion loss of 2 dB in a frequency range of equal to or more than 20 GHz.

8. The termination circuit according to claim 1, wherein the high frequency signal of equal to or more than 25 GHz propagates through the transmission line.

9. A wireless communication device comprising the termination circuit according to claim 1.

10. A termination method comprising connecting one or a plurality of capacitive elements connected in cascade to an end of a transmission line through which a high frequency signal propagates to terminate the transmission line.
